(19) United States
(12) Patent Application Publication
(10) Pub. No.: US 2019/0011497 A1
(43) Pub. Date: Jan. 10, 2019

(54) Test Fixture with Sintered Connections Between Mother Board and Daughter Board

(71) Applicant: Texas Instruments Incorporated, Dallas, TX (US)

(72) Inventor: Randal LeRay Newby, Raymond, NH (US)

(21) Appl. No.: 15/644,817

(22) Filed: Jul. 9, 2017

(51) Int. Cl. G01R 31/28; H05K 3/40; H05K 3/36; H05K 1/11; H05K 1/14; G01R 1/073; G01R 3/00

(52) U.S. Cl. CPC G01R 31/2889; H05K 3/4007; H05K 3/36; H05K 1/111; H05K 2201/09036; G01R 1/07378; G01R 3/00; G01R 31/2834; H05K 1/144

(57) ABSTRACT

A test fixture includes a mother board that has test signal lines configured to couple to a test station. The mother board includes a recessed region with contact pads coupled to the test signal lines. A daughter board is engaged with the recessed region such that a top surface of the daughter board is approximately coplanar with a top surface of the mother board. The daughter board includes test signal lines coupled to contact pads on the daughter board. The contact pads on the daughter board align with the contact pads on the mother board and are permanently coupled by sintered bonds.

### FIELD OF THE DISCLOSURE

This disclosure relates to a test fixture that includes a mother board and a daughter board

### BACKGROUND OF THE DISCLOSURE

Automatic test equipment (ATE) may be an apparatus that performs tests on a device, known as the device under test (DUT), equipment under test (EUT) or unit under test (UUT), using automation to quickly perform measurements and evaluate the test results.

ATE systems typically interface with an automated placement tool that physically places the DUT on an Interface Test Adapter (ITA) so that it can be measured by the equipment. The ITA may be a device that makes electronic connections between the ATE and the Device or Unit Under Test. The ITA may also contain additional circuitry to adapt signals between the ATE and the DUT and has physical facilities to mount the DUT. A socket may be used to bridge the connection between the ITA and the DUT. A socket must survive the rigorous demands of a production floor, so they may be replaced frequently.

### SUMMARY OF THE DISCLOSURE

A test fixture includes a mother board that has test signal lines configured to couple to a test station. The mother board includes a recessed region with contact pads coupled to the test signal lines. A daughter board is positioned in the recessed region such that a top surface of the daughter board is approximately coplanar with a top surface of the mother board. The daughter board includes test signal lines coupled to contact pads on the daughter board. The contact pads on the daughter board align with the contact pads on the mother board and are permanently coupled by sintered bonds.

### BRIEF DESCRIPTION OF THE DRAWINGS

Particular embodiments in accordance with the disclosure will now be described, by way of example only, and with reference to the accompanying drawings:

FIG. 1 is a block diagram of an example ATE system;

FIG. 2 is a more detailed illustration of an example handler interface board (HIB) for the test system of FIG. 1;

FIGS. 3-6 illustrate more details of the example HIB of FIG. 2;

FIG. 7 is a plot illustrating melting point vs. particle size in a sintering process;

FIG. 8 illustrates a method for fabricating a test fixture; and

FIG. 9 illustrates an alternative embodiment.

Other features of the present embodiments will be apparent from the accompanying drawings and from the detailed description that follows.

### DETAILED DESCRIPTION OF EMBODIMENTS OF THE DISCLOSURE

Specific embodiments of the disclosure will now be described in detail with reference to the accompanying figures. Like elements in the various figures are denoted by like reference numerals for consistency. In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

A system on a chip (SoC) is an integrated circuit (IC) that integrates several components of a computer or other electronic system. It may contain digital, analog, mixed-signal, and often radio-frequency functions-all on a single substrate. An SoC may integrate a microcontroller or microprocessor with advanced peripherals such as: graphics processing units (GPU), Wi-Fi modules, coprocessors, etc. Testing SoC's may require specialized test equipment in order to adequately test the various components included within the SoC.

In many cases, a single SoC design may be packaged in different packages or may have different pinout configurations for specialized applications. A different interface test adaptor (ITA) may be required for each package or pinout configuration in order to test each version of the SoC on a given automatic test system. Providing multiple ITAs may increase the cost of testing the SoC, especially in low volume applications.

A flexible mother/daughter ITA configuration will now be disclosed that may reduce test adaptor costs for integrated circuits or other types of electronic modules.

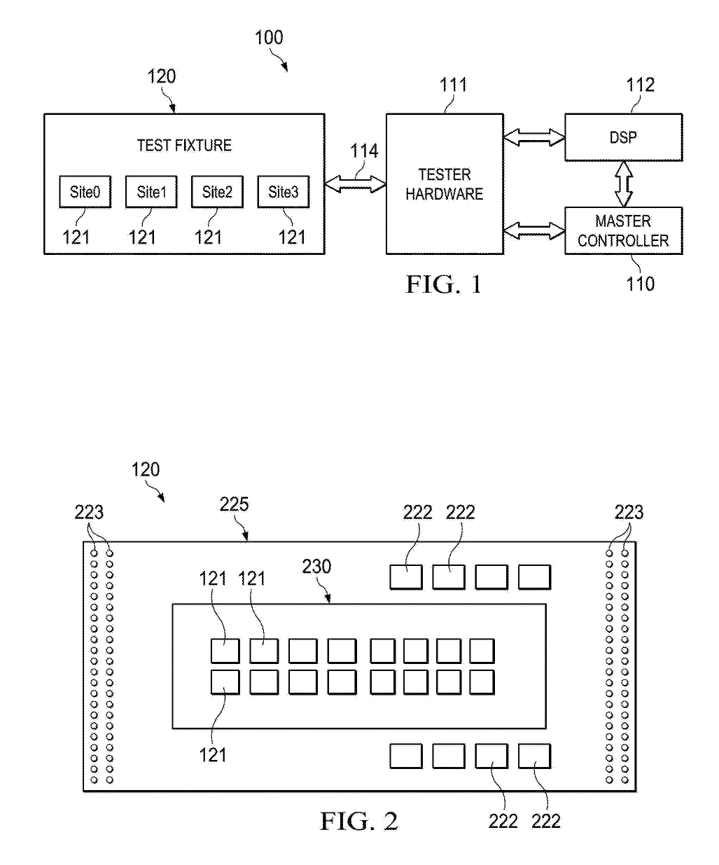

FIG. 1 is a block diagram of an example ATE system 100. Semiconductor ATE systems are available from several manufacturers, such as Teradyne, Advantest, Verigy, etc. Example ATE system 100 includes a master controller 110 that executes test software that synchronizes one or more source and capture instruments that are included within tester hardware 111. Digital signal processing (DSP) resources 112 may be used to analyze test result signals and/or to generate test stimulus signals, for example.

Test hardware 111 may include various resources, such as: digitally controlled power supplies, voltage/current sources (VIs), digital channel pin cards with parametric measurement units (PMUs), synchronous tester wide programmable divided clocks/reference clocks derived from phase locked loops (PLLs), arbitrary waveform generator (AWG) and digitizer, high(er) precision audio band waveform generator and digitizer, RF sources and RF measurement instruments, etc.

The Device Under Test (DUT) may be physically connected to the ATE by a robotic machine called a Handler or Prober (not shown) through a customized ITA or “test fixture” 120 that adapts the ATE's resources to the DUT. ITA 120 may also be referred to as a “handler interface board” (HIB). HIB 120 may be connected to the tester hardware 111 via an interface 114 that may include an array of pogo pins that are brought into contact with signal pads on HIB 120.

HIB 120 may include a several sockets that provide multiple sites for DUTs, such as indicated at 121.

FIG. 2 is a more detailed illustration of an example handler interface board 120 for the test system 100 of FIG. 1. Various embodiments may be configured for ATE systems from various vendors. In this example, HIB 120 is a large test fixture, approximately 18 inches wide by 31.5 inches long and is typically configured to include 8-16 sockets 121. Various circuitry and devices as indicated generally at 222 may be included on HIB 120, such as latches, drivers, buffers, relays, etc. Additional resource may also be included on the HIB, such as: RF transmitters and/or receivers, amplifiers, filters; mixed-signal circuits such as DACs/ADCs; PLLs with reference clock inputs and divided outputs; power management blocks such as LDOs and switchers; high-speed digital PCIe, USB, DDR buses; analog voltage/current reference inputs for internal circuits; other digital GPIOs (General purpose I/Os), etc.

Various signal pads, such as indicated at 223 may be connected to various signal lines that are in turn coupled to sockets 121 and/or circuitry 122. The signal pads provide contact points for pogo pins for tester interface 114, referring to FIG. 1.

The time and effort required to design, layout, and test each HIB may be significant. Typically, only a few copies of each HIB may be needed, so the fabrication cost of each one may be significant. For example, it may cost $7800 per board to fabricate three HIBs, depending on the layer count and complexity.

HIB 120 may be partitioned into two separate printed circuit boards (PCB), such as a mother board 225 and a daughter board 230. While the term “board” is used herein, a PCB may also be referred to as a “card,” or other similar terms. These two boards may be permanently interconnected, as will be described in detail below. While a rectangular outline for daughter board 230 is illustrated here, other embodiments may use other shapes, such as square, oval, etc. While a single daughter board 230 that is approximately eight inches wide and sixteen inches long is illustrated here, another embodiment may use a larger or a smaller size daughter board. Another embodiment may use two or more daughter boards, for example.

Another embodiment may use a larger or a smaller HIB while still providing a mother board/daughter board configuration. For example, the test system may also support an HIB that may be smaller, such as 18 inches wide by 23.5 inches long. In this case, the daughter card may be made smaller to fit within the confines of the smaller HIB outline.

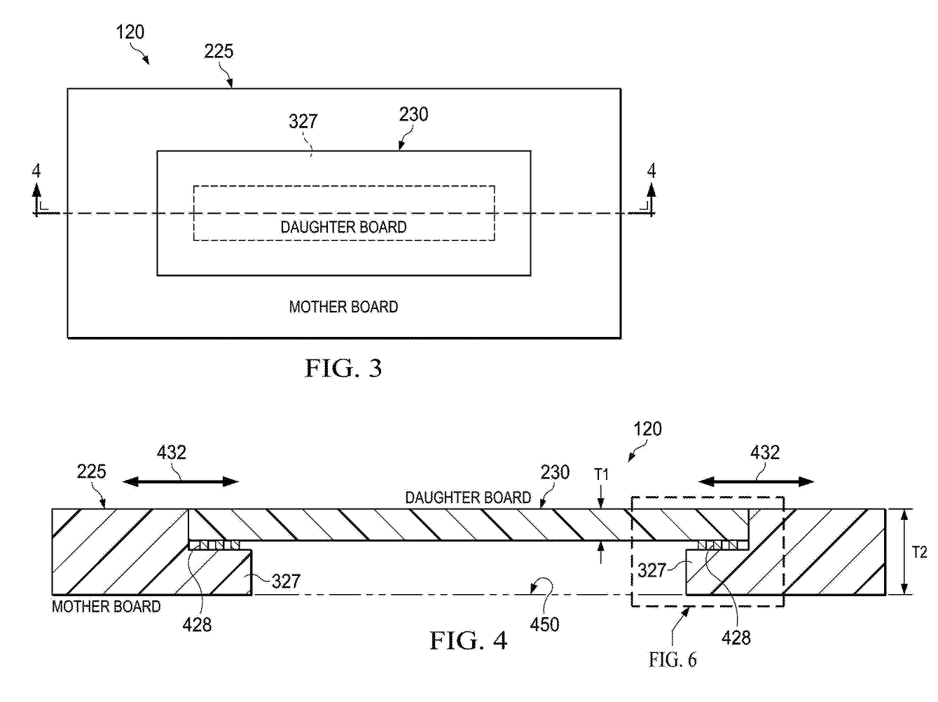

FIG. 3 illustrates a simplified top view of the example HIB 120. As mentioned above, a set of pogo pins may be used to provide a connection between HIB 120 and interface 114 of ATE 100 (see FIG. 1). A handler machine that loads and unloads DUT top/from sockets 121 must be adjusted based on the height of the sockets 121. It is therefore desirable that the top surface of daughter board 230 be approximately coplanar with the top surface of mother board 225 so that height adjustments are not required for the pogo pins and handler machine. In order to provide a uniform height HIB 120, daughter board 230 may be inset into mother board 225 by engaging a recessed region 327, which is configured to provide support and connectivity to the daughter board 230.

FIG. 4 is a side sectional view of HIB 120 showing a stepped recessed region 327. A set of contacts 428 may be placed between mother board 225 and daughter board 230 on recessed region 327 to provide connectivity between the two boards. A large number of contacts 428 may be required, depending on the number of test sockets 121 (see FIG. 2) that are located on daughter board 230. For example, a daughter board with sixteen test sockets may require up to 5000 contacts to provide power, ground and test signals between daughter board 230 and mother board 225.

In this example, daughter board 230 has a thickness T1 that is thinner than the thickness T2 of mother board 225 so that the top surface of daughter board 230 may be approximately coplanar with the top surface of mother board 225, as indicated at 432. The mother board and daughter board do not need to be exactly coplanar, just approximately coplanar so that any automated handling equipment used handle various test fixtures that may be automatically loaded onto test system 100 need not be adjusted to compensate for a difference in height between the top surface daughter board 230 and the top surface of mother board 225, as indicated at 432.

In this example, an opening 450 is provided in mother board 225 under daughter board 230. In this case, recessed region 327 circumscribes, or laterally surrounds, daughter board 230. In another embodiment, recessed region 327 may extend across the entire area under daughter board 230, for example.

In another embodiment, a thicker daughter board may be used by providing a corresponding step, or recessed region, around the outside of the daughter board so that the top surface of the daughter board remains coplanar with the top surface of the mother board when the daughter board is engaged with the mother board. In this case, area 450 may need to be open to accommodate the thicker daughter board.

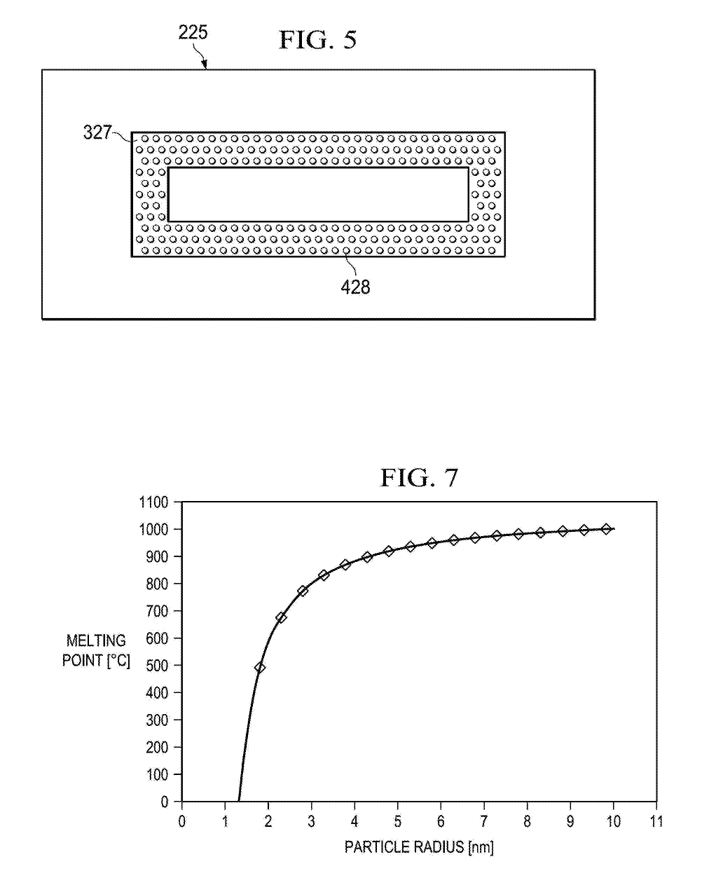

FIG. 5 is a top view of mother board 225 showing recessed region 327 with an array of contacts 428. As mentioned above, some embodiments may include a large number of contacts, such as 5000 contacts, for example. Other embodiments may have a lower number or a larger number of contacts, as needed.

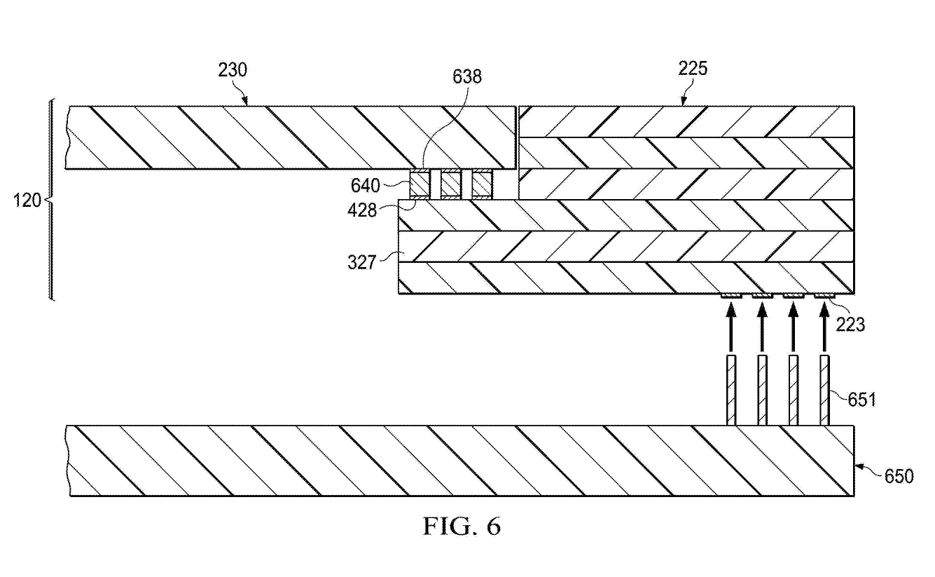

FIG. 6 illustrates a portion of sectional view 4-4 (see FIG. 3) of HIB 120 in more detail. This figure also illustrates a portion of the pogo pins 651 that may be mounted on an interface board 650 that is part of tester interface 114, referring to FIG. 1. As mentioned above, pogo pins 651 may be aligned to contact various pads 223 on mother board 225.

Mother board 225 may be a multilayer printed circuit board that allows routing signal lines from the set of contacts 428 to the set of pads 223 and to/from various circuits 222, as shown on FIG. 2. Similarly, daughter board 230 may be a multilayer printed circuit board that allows routing signal lines from the set of contacts 638 to/from various sockets 221, as shown on FIG. 2, and/or other circuitry on daughter board 230. The design and fabrication of printed circuit boards is well known and need not be described in detail herein.

A permanent, reliable connection may be made between the set of contacts 428 and the set of contacts 638 using a sintering process. An inkjet printer may be used to deposit a series of droplets that contain metal nanoparticles onto the metal pads 428 and/or metal pads 638. Fabrication of three dimensional structures using ink jet printers or similar printers that can “print” various polymer materials is well known and need not be described in further detail herein. Printing allows for the rapid and low-cost deposition of thick dielectric and metallic layers, such as 0.1 um-1000 um thick, for example, while also allowing for fine feature sizes, such as 20 um feature sizes, for example.

The ink may include a solvent or several solvents to match rheology and surface tension, and metallic nanoparticles. The size of the nanoparticle may be in a range of 2-100 nm, for example. The ink may also include a dispersant such as polyvinylpyrrolidone (PVP) or be charge dispersed to prevent agglomeration of the particles. The ink may also include binders such as polymer epoxies, and other known or later developed ink additives.

The film residue that is left from the ink may then be cured in the case of solvent or dispersant based ink where solvent or dispersant is evaporated. Curing may be thermal (50-250 C), UV, Infrared, Flash Lamp, or of another form that is compatible with the ink being used.

In this example, the metal nanoparticles may be copper, or a mixture of copper and silver, for example. In another embodiment, the nanoparticles may be a mixture of copper and graphene, or copper and graphite, for example. The graphite/grapheme mixtures allow for a higher current density without electromigration. In another embodiment, the nanoparticles may be copper oxide that is later reduced back copper during a sintering step that will be described in more detail below.

Referring still to FIG. 6, a sintering process may convert an ink bump that is formed by metal particles into a solid structure 640. Sintering is the process of compacting and forming a solid mass of material by heat and/or pressure without melting it to the point of liquefaction. The atoms in the materials may diffuse across the boundaries of the particles, fusing the particles together and creating one solid piece. Because the sintering temperature does not have to reach the melting point of the material, sintering is chosen as the shaping process for materials with extremely high melting points. Most, if not all, metals can be sintered. This applies especially to pure metals produced in vacuum which suffer no surface contamination.

Sintering the nanoparticles deposited on pads 428 on the mother board and/or pads 638 on the daughter produces a solid structure 640 that forms a sintered metal bond between each mother board pad 428 and corresponding daughter board pad 638. Adhesion of the sintered metal to the metal surface of the pads may occur in three manners: (1) van der Waals forces, (2) mechanical adhesion/roughness, (3) through the nanoparticle or surface chemical diffusion into the other. Unlike a joint formed by eutectic solder, sintered metal bond 640 will not melt and degrade the bond if it is heated a second time.

Each sintered metal bond is typically porous as a result of spaces that remain between the nanoparticles after the sintering process. However, a sintering process may be continued until porosity is reduced or eliminated. A porous sintered bond may reduce thermo-mechanical reliability risk due to an ability to flex in response to stress applied to the bond by thermal or mechanical forces. The amount of porosity may be controlled by controlling one or more aspects of the sintering process, such as: selecting the size of the nanoparticles, selecting the temperature profile or other process parameters used to perform the sintering process, etc. Another way to control porosity is to add a sacrificial nanoparticle to the ink, such as poly-methyl methacrylate, or other polymer, silica, etc; then remove these particles during the sintering or after the sintering to increase the porosity. A typical nanoparticle sintered metal bond may have a porosity of approximately 20%. Generally, porosity may be selected to fall within a range of 0%-50% while still providing good current carrying capacity and structural integrity.

Sintering may be performed in a number of ways. For example, the boards may be heated to an elevated temperature but need not be heated to the melting point of the metal that forms the nanoparticles. For example, copper nanoparticles may be heated to a range of 80-300 C to form a solid structure. For comparison, the melting point of copper is 1,085 C.

While deposition of nanoparticles of copper or other conductive material using an inkjet printer is used in this embodiment, other embodiments may use other known or later developed processes to deposit bumps of powdered conductive material on either or both sets of contacts 428, 638 that may then be sintered to form sintered metal bonds similar to bonds 640. In this case, the conductive particles may be larger than nanoparticles, for example.

FIG. 7 is a plot illustrating melting point vs. particle size for copper nanoparticles in a sintering process. The small nanoparticles may melt together at very low temperatures; however, as they melt together they get larger which causes the “bulk” melting temperature of the nanoparticles to go up. This causes an irreversible process in which higher temperature will only make the particles get bigger and thus melt at an even higher temperature. Thus, once the small nanoparticles are melted, the resulting structure cannot be un-melted like solder, unless the melting point of the bulk metal is reached. Note in FIG. 7, while sintering may occur at a temperature range of 80-300 C for copper nanoparticles, the resulting sintered metal bond cannot be re-melted unless the temperature of the sintered metal structure is raised to 1085 C, which is the melting point of bulk copper.

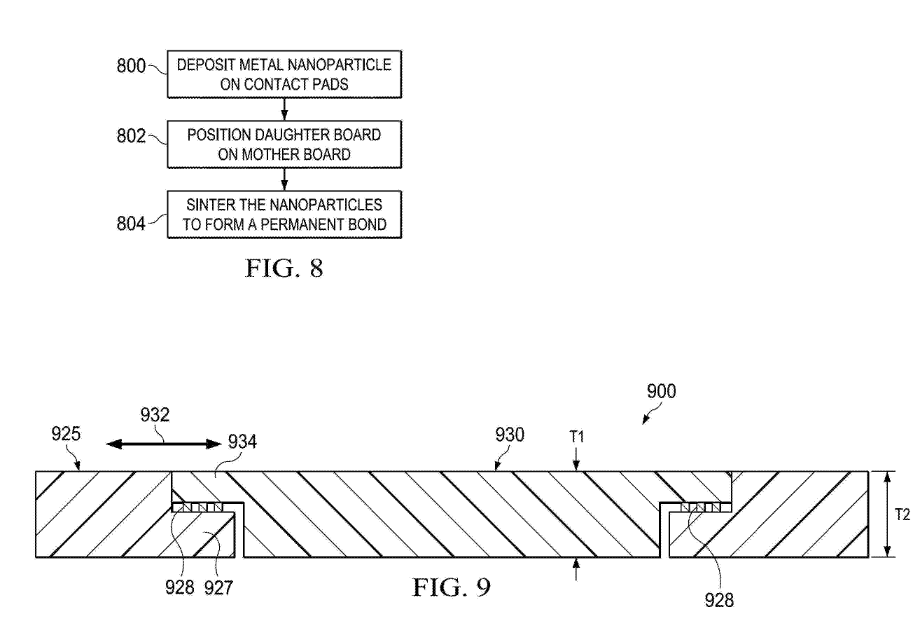

FIG. 8 illustrates a method for fabricating a test fixture. Metal nanoparticles may be deposited on contact pads on a mother board and/or on contact pads on a daughter board as indicated at 800, as described in more detail above. For example, an inkjet printer may be used to deposit a series of droplets that contain metal nanoparticles onto the metal pads of the mother board and/or the daughter board.

The daughter board may be positioned on the mother board such that the contact pads on the daughter board align with the contact pads on the mother board, as indicated at 802. Referring again to FIG. 4, the daughter board may be positioned in a recessed step so that a top surface of the daughter board is coplanar with a top surface of the mother board.

The metal nanoparticles may be sintered as indicated at 806 to form a permanent bond between the contact pads on the daughter board and the contact pads on the mother board. Sintering may be performed by heating to an elevated temperature but need not be heated to the melting point of the metal that forms the nanoparticles. While sintering may occur at a temperature range of 80-300 C for copper nanoparticles, the resulting sintered metal bond cannot be re-melted unless the temperature of the sintered metal structure is raised to 1085 C, which is the melting point of bulk copper.

In another embodiment, copper oxide nanoparticles, for example, may be sintered using a Xenon flash lamp using a known or later developed photon sintering process.

In another embodiment, copper oxide nanoparticles, for example, may be sintered in a reducing atmosphere using a known or later developed forming gas or formic acid sintering process. In this case, the copper oxide is converted back to pure copper by the formic acid process. Typically, this process may be performed at a temperature in the range of 200-250 C.

In this manner, a daughter board may be fabricated and attached to a mother board in which sintered metal bonds are formed between the contacts on the daughter board and the contact regions of the mother board. Sintering may be performed at a temperature that is much lower than the melting point of the metal nanoparticles being used. This allows the use of organic substrates for the printed circuit boards, for example, that would not withstand a higher temperature process.

A sufficient volume of nanoparticle material may be printed for each bump in order to compensate for expected non-coplanarity of the mother/daughter board interface surface.

Sintering eliminates the problem of intermetallic growth between copper and tin-based Pb-free solder. Brittle solder fatigue and thermally activated void growth in solder may be eliminated by the sintered metal bond. Current carrying capacity of the joint may also be enhanced.

Thus, in this manner reliable HIB test fixture may be made using a mother board and one or more daughter boards. By maintaining surface coplanarity, no adjustments are required to supporting handlers and test equipment pogo pin interfaces when different HIBs are presented to an ATE system.

The mother board may be designed to bring all the tester resources out to the daughter board. The daughter board may contain any needed circuitry and make the connections to the DUT. This method greatly reduces the test hardware cost for each device, along with reducing the design and fabrication time of the HIB fixture.

This mother/daughter approach also has advantages from a quality standpoint. For a complex HIB PCB design, with tight features, there is a possibility that there may be a manufacturing defect, hence fallout during the manufacturing of the HIB. When the mother board and daughter board are built separately, they may be tested separately before sintering, so it is known that they are good PCBs. The smaller daughter board is less likely to have manufacturing issues.

From a cost standpoint, consider an SoC device which has five package options where it is common practice to buy three copies of each test fixture for use during a production run. In this case, a single SoC would require fifteen HIBs with five different designs. If each copy costs $7800 to manufacture, then the total cost would be $117K plus the design cost.

To produce a mother/daughter board configuration as disclosed herein, a single mother board could be designed and 15 identical copies produced, at a lower cost per board. Five different daughter boards would be needed, but they would be much simpler to design and manufacture. In this case, each of the 15 mother boards may be fabricated at a cost of $1810 for a total of $27,150 and each of the daughter boards may cost $2553 for a total of $38,295, for example. The total test fixture production cost would therefore be $65,445. This is a savings of 42%.

The savings could be even larger if one main mother board is created and produced in quantity and then simple daughter boards are created for each device that will be put onto the tester.

Insetting the daughter board into the mother board eliminates any Z axis height issues in the ATE system and associated DUT handling machines. Sintering the mother board to daughter board connections eliminates reliability problems that might result from hundreds or thousands of connections between the two boards.

FIG. 9 illustrates an alternative embodiment of a test fixture 900. In this example, mother board 925 may be similar to mother board 225 as described above with regard to FIGS. 2-6. FIG. 9 is a cross sectional view from a section line similar to section line 4-4 on FIG. 3. Contacts 928 in recessed region 927 allow a daughter board 930 to be placed in the recessed region and permanently coupled using sintered contacts, as described above in more detail.

In this example, daughter board 930 may have a thickness T1 that is thicker than the depth of recessed region 827. In order to maintain coplanarity of the top surfaces as indicated at 932, the daughter board 930 may also have a recessed region 934 around its periphery.

### Other Embodiments

While the disclosure has been described with reference to illustrative embodiments, this description is not intended to be construed in a limiting sense. Various other embodiments of the disclosure will be apparent to persons skilled in the art upon reference to this description. For example, while copper pads were described herein, other embodiments may use other types of metal for the pads, such as aluminum, gold, nickel, etc.

While a mother/daughter board combination with a coplanar top surface has been described herein, in another embodiment the daughter board may be mounted on top of the mother board without using a recessed region. In this case, the advantage of coplanarity is lost, but the reliability of sintered contacts in the test fixture is maintained.

Different metallic nanoparticles may be used in various embodiments, such as: copper, copper-silver hybrid, copper oxide, copper graphite, copper graphene, etc.

While testing of SoCs was described herein, many other types of integrated circuits and electronic modules may be tested by providing a test fixture as described herein that has a daughter board with an appropriate socket or other type connector to allow the DUT to be mounted on the test fixture.

Certain terms are used throughout the description and the claims to refer to particular system components. As one skilled in the art will appreciate, components in digital systems may be referred to by different names and/or may be combined in ways not shown herein without departing from the described functionality. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” and derivatives thereof are intended to mean an indirect, direct, optical, and/or wireless electrical connection. Thus, if a first device couples to a second device, that connection may be through a direct electrical connection, through an indirect electrical connection via other devices and connections, through an optical electrical connection, and/or through a wireless electrical connection.

It is therefore contemplated that the appended claims will cover any such modifications of the embodiments as fall within the true scope and spirit of the disclosure.

What is claimed is:

1. A test fixture comprising:
a mother board having first test signal lines configured to couple to a test station, the mother board including first contact pads coupled to the test signal lines; and
a daughter board having second test signal lines coupled to second contact pads on the daughter board, wherein the second contact pads align with the first contact pads and are coupled to the first contact pads by sintered bonds.

2. The test fixture of claim 1, wherein the mother board has a recessed region circumscribing the daughter board.

3. The test fixture of claim 2, in which a top surface of the daughter board is approximately coplanar with a top surface of the mother board.

4. The test fixture of claim 2, in which recessed region has a depth, and in which the daughter card has a thickness approximately equal to the depth of the recessed region.

5. The test fixture of claim 2, in which the daughter board has a recessed region configured to engage with the recessed region on the mother board.

6. The test fixture of claim 5, in which the recessed region on the mother board has a depth, and in which the daughter board has a thickness larger than the depth of the recessed region on the mother board.

7. A test fixture comprising:
a mother board having first test signal lines configured to couple to a test station, the mother board including first contact pads coupled to the test signal lines; and
a daughter board having second test signal lines coupled to second contact pads on the daughter board, wherein the second contact pads align with the first contact pads and are coupled to the first contact pads by sintered bonds, and wherein the mother board has a recessed region circumscribing the daughter board.

8. The test fixture of claim 7, in which the recessed region has a depth, and in which the daughter card has a thickness approximately equal to the depth of the recessed region.

9. The test fixture of claim 7, in which the daughter board has a recessed region configured to engage with the recessed region on the mother board.

10. The test fixture of claim 9, in which the recessed region on the mother board has a depth, and in which the daughter board has a thickness larger than the depth of the recessed region on the mother board.

11. A method for making a test fixture, the method comprising:
depositing conductive particles on contact pads on a mother board and/or on contact pads on a daughter board;
positioning the daughter board on the mother board such that the contact pads on the daughter board align with the contact pads on the mother board; and
sintering the conductive particles to form a bond between the contact pads on the daughter board and the contact pads on the mother board.

12. The method of claim 11, wherein the mother board includes a recessed region, and in which positioning the daughter board includes engaging the daughter board with the recessed region such that a top surface of the daughter board is approximately coplanar with a top surface of the mother board.

13. The method of claim 11, in which sintering is performed by heating the mother board and daughter board to a temperature less than the melting point of the bulk material comprising the conductive particles.
